(19) United States
(12) Patent Application Publication
(10) Pub. No.: US 2015/0219953 A1
(43) Pub. Date: Aug. 6, 2015

(54) LCD DEVICE

(71) Applicants: Shih Hsiang Chen, Shenzhen (CN); Gang Yu, Shenzhen (CN); Ruilian Yang, Shenzhen (CN)

(72) Inventors: Shih Hsiang Chen, Shenzhen (CN); Gang Yu, Shenzhen (CN); Ruilian Yang, Shenzhen (CN)

(73) Assignee: Shenzhen China Star Optoelectronics Technology Co., Ltd., Guangming District, Guangdong (CN)

(21) Appl. No.: 13/703,362

(22) PCT Filed: Sep. 6, 2012
(86) PCT No.: PCT/CN2012/081045

§ 371 Date: Mar. 29, 2015

(30) Foreign Application Priority Data
Aug. 16, 2012 (CN) 201210292147.3

(51) Int. Cl. G02F 1/1333; G02F 1/1335; H05K 5/00

(52) U.S. Cl. CPC G02F 1/133308; H05K 5/0008; G02F 1/133528; G02F 1/133524; G02F 2001/133317; G02F 2001/133314

(57) ABSTRACT

The present invention discloses an LCD device, which includes a display panel, a connecting part, a back cover, and a locking part. The connecting part is fixed on one side of the display panel. The back cover is disposed on the side of the display panel having the connecting part and has a through hole corresponding to the connecting part. The locking part includes a base and an extending portion extending from the base. The base abuts against the back cover, and the extending portion penetrating the through hole and locked in the connecting part, so that the display panel is fixed on the back cover to achieve the LCD device without a bezel.

### FIELD OF THE INVENTION

The present invention relates to a display device, and especially to a liquid crystal display (LCD) device without a bezel.

### BACKGROUND OF THE INVENTION

An LCD device has the advantages of low power consumption, low radiation, and so on; therefore, it is widely used in display devices nowadays. With the continuous advancement of LCD technology, the LCD device with a large size and a thin profile increasingly becomes a mainstream in market demand, so the LCD follows a current trend toward a narrow bezel

However, assembly structures of the typical LCD device generally includes a front bezel, a display panel, a backlight module, and back cover. The front bezel and the back cover are utilized to sandwich the display panel and the backlight module therebetween and to fix them. In the assembling process, the front bezel and the back cover need to be engage with each other; thus, the front bezel and the back cover have corresponding coupling mechanism that are respectively disposed thereon. In general, said coupling mechanism is screw holes and screw nuts. However, whatever the coupling mechanism, certain area of the front bezel will be occupied, such that the front bezel is difficult to be designed as a narrower structure. Therefore, the demand for the narrow bezel even no bezel can not be achieved.

### SUMMARY OF THE INVENTION

An objective of the present invention is to provide an LCD device, which can abandon the design of the front bezel to achieve the demand of no bezel.

To achieve the foregoing objective, the present invention provides an LCD device, which includes a display panel, a connecting part, a back cover, and a locking part. The connecting part is fixed on one side of the display panel. The back cover is disposed on the side of the display panel having the connecting part and has a through hole corresponding to the connecting part. The locking part includes a base and an extending portion extending from the base. The base abuts against the back cover, and the extending portion penetrates the through hole and is locked in the connecting part, so that the display panel is fixed on the back cover.

In the LCD device of one preferred embodiment, the connecting part has a threaded hole, and the extending portion of the locking part has external threads matching the threaded hole. In the embodiment, the connecting part is a rivet nut; the locking part is a screw. In another embodiment, the connecting part is a nut; the locking part is a bolt.

In the LCD device of the present invention, the connecting part is fixed on the side of the display panel by glue.

In the LCD device of one preferred embodiment, the display panel includes an upper substrate, a lower substrate, and a liquid crystal layer between the upper and lower substrates; the connecting part is stuck on an outer side of the lower substrate. More specifically, the LCD device further includes a polarizer between the lower substrate and the connecting part.

In the LCD device of one preferred embodiment, the LCD device further includes a light guide plate and a plurality of optical films between the display panel and the back cover. The optical films have a perforation, so that the connecting part penetrates the perforation of the optical films.

In the LCD device of one preferred embodiment, the LCD device further includes a mold frame disposed between the display panel and the back cover, and the mold frame is utilized to support the display panel on the back cover. The mold frame is disposed on a periphery of the display panel and coupled to edges of the back cover.

In comparison with the prior art, the connecting part implemented by the rivet nut or the nut is stuck on the side of the display panel, and the display panel is locked on the back cover through the locking part; therefore, the display panel dose not need to be fixed by the front bezel from the outside of the display panel. As a result, the objective of the present invention for the LCD device without bezel can be achieved.

It is to be understood that both the foregoing general description and the following detailed description of the present invention are exemplary and explanatory and are intended to provide further explanation of the invention as claimed.

### DESCRIPTION OF THE DRAWINGS

FIG. 1 is a partial sectional view illustrating an LCD device according to one preferred embodiment of the present invention; and

FIG. 2 is a partial sectional view illustrating an LCD device according to another preferred embodiment of the present invention.

### DETAILED DESCRIPTION OF THE PREFERRED EMBODIMENTS

Descriptions of the following embodiments refer to attached drawings which are utilized to exemplify specific embodiments.

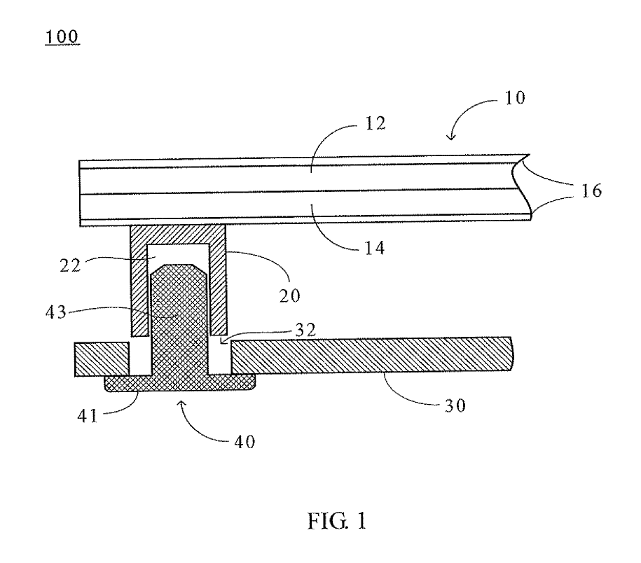

Referring to FIG. 1, FIG. 1 is a partial sectional view illustrating an LCD device according to one preferred embodiment of the present invention. The LCD device 100 of the preferred embodiment includes a display panel 10, a plurality of connecting parts 20, a back cover 30, and a plurality of locking parts 40. In order to explain clearly, the drawing only shows an edge of the LCD device 100 of the preferred embodiment, and only shows a single connecting part 20 and a single locking part 40.

The connecting part 20 is fixed on one side of the display panel 10. Specifically, the display panel 10 includes an upper substrate 12, a lower substrate 14, and a liquid crystal layer (not shown) between the upper substrate 12 and the lower substrate 14. The connecting part 20 is stuck on an outer side of the lower substrate 14. It is worth mentioning that a polarizer 16 is disposed on outer surfaces of the upper substrate 12 and the lower substrate 14. That is, there is a polarizer 16 between the lower substrate 14 and the connecting part 20. It is worth mentioning that the connecting part 20 is fixed on the side of the display panel 10 by glue. However, the fixing manner is not limited to be implemented by glue in the present invention; it can also be implemented by other fixing manners.

The back cover 30 is disposed on the side (i.e. an opposite side of a display side) of the display panel having the connecting part 20 and has a through hole 32 corresponding to the connecting part 20. The locking part 40 includes a base 41 and an extending portion 43 extending from the base 41. The base 41 abuts against the back cover 30, and the extending portion 43 penetrates the through hole 32 and locked in the connecting part 20, so that the display panel 10 is fixed on the back cover 30. It is worth mentioning that the plurality of connecting parts 20 and locking parts 40 are distributed on four edges of the display panel 10 and the back cover 30, so as to lock display panel 10 onto the back cover 30.

In the embodiment, the connecting part 20 has a threaded hole 22; the extending portion 43 of the locking part 40 has external threads (not shown) matching the threaded hole. More specifically, the connecting part 20 is a rivet nut; the locking part 40 is a screw. In the assembling process, the screw is fastened into the rivet nut, thereby fixing the display panel 10 onto the back cover 30. In another embodiment, the connecting part 20 is a nut; the locking part 40 is a bolt. Similarly, in the assembling process, the bolt is fastened into the nut, thereby fixing the display panel 10 onto the back cover 30.

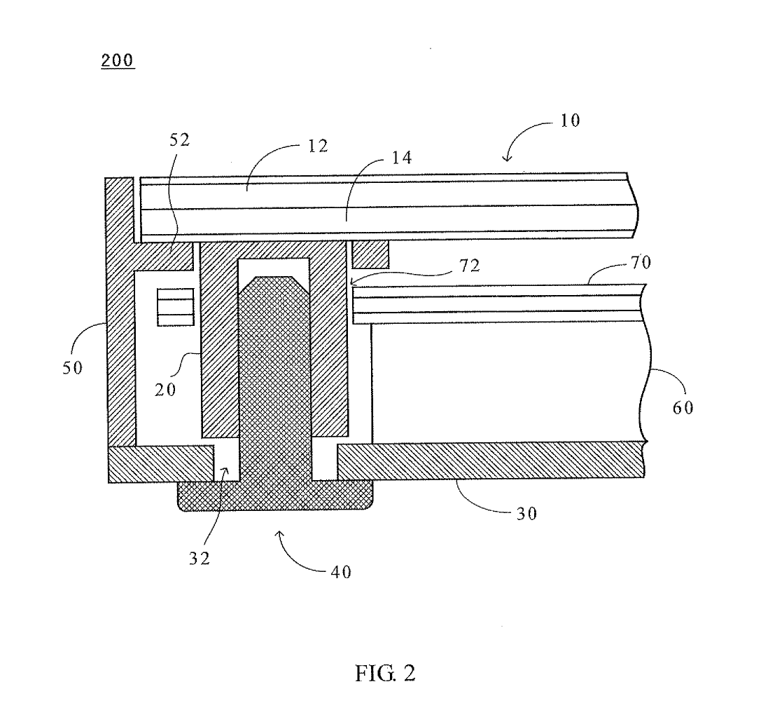

An LCD device of another preferred embodiment of the present invention will be explained in the following. Referring to FIG. 2, FIG. 2 is a partial sectional view illustrating an LCD device according to another preferred embodiment of the present invention. The LCD device 200 of the preferred embodiment includes a display panel 10, a plurality of connecting part 20, a back cover 30, a plurality of locking part 40, and a mold frame 50. Similarly, in order to explain clearly, the drawing only shows an edge of the LCD device 100 of the preferred embodiment, and only shows a single connecting part 20 and a single locking part 40.

Similarly, the connecting part 20 is fixed on one side of the display panel 10. The display panel 10 includes an upper substrate 12, a lower substrate 14, and a liquid crystal layer (not shown) between the upper substrate 12 and the lower substrate 14. The connecting part 20 is stuck on an outer side of the lower substrate 14. It is worth mentioning that a polarizer 16 is disposed on outer surfaces of the upper substrate 12 and the lower substrate 14. That is, there is a polarizer 16 between the lower substrate 14 and the connecting part 20. It is worth mentioning that the connecting part 20 is fixed on the side of the display panel 10 by glue.

The back cover 30 is disposed on the side (i.e. an opposite side of a display side) of the display panel having the connecting part 20 and has a through hole 32 corresponding to the connecting part 20. The locking part 40 includes a base 41 and an extending portion 43 extending from the base 41. The base 41 abuts against the back cover 30, and the extending portion 43 penetrates the through hole 32 and locked in the connecting part 20, so that the display panel 10 is fixed on the back cover 30.

In the embodiment, the connecting part 20 has a threaded hole 22; the extending portion 43 of the locking part 40 has external threads (not shown) matching the threaded hole. More specifically, the connecting part 20 is a rivet nut; the locking part 40 is a screw. In the assembling process, the screw is fastened into the rivet nut, thereby fixing the display panel 10 onto the back cover 30. In another embodiment, the connecting part 20 is a nut; the locking part 40 is a bolt. Similarly, in the assembling process, the bolt is fastened into the nut, thereby fixing the display panel 10 onto the back cover 30.

One difference from the above-mentioned embodiment is that there are a light guide plate 60 and a plurality of optical films 70 between the display panel 10 and the back cover 30. The optical films 70 have a perforation 72, so that the connecting part 20 penetrates the perforation 72 of the optical films 70 for stabilizing the position of the optical films 70.

As shown in FIG. 2, the mold frame 50 is disposed between the display panel 10 and the back cover 30, and utilized to support the display panel 10 on the back cover 30, so as to reinforce the fixing effect of a combination of the connecting part 20 and the locking part 40. On the other hand, the mold frame 50 also can replace the front bezel to envelop the spacing between the sides of the display panel 10 and the back cover 30. Specifically, the mold frame 50 is disposed on a periphery of the display panel 10 and coupled to edges of the back cover 30. Moreover, the mold frame 50 has a platform 52 to support the display panel 10, and the connecting part 30 penetrates the platform 52 of the mold frame 50. However, specific shapes of the mold frame 50 are not limited as the drawing shown.

In summary, the connecting part 20 implemented by the rivet nut or the nut is stuck on the side of the display panel 10, and the display panel 10 is locked on the back cover 30 through the locking part 40; therefore, the display panel 10 dose not need to be fixed by the front bezel from the outside of the display panel 10. As a result, the objective of the present invention for the LCD device without bezel can be achieved.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A liquid crystal display (LCD) device, comprising
a display panel;
a connecting part fixed on one side of the display panel;
a back cover disposed on the side of the display panel having the connecting part, and having a through hole corresponding to the connecting part;
a mold frame disposed between the display panel and the back cover, the mold frame utilized to support the display panel on the back cover; and
a locking part comprising a base and an extending portion extending from the base, the base abutting against the back cover, and the extending portion penetrating the through hole and locked in the connecting part, so that the display panel is fixed on the back cover.

2. The LCD device according to claim 1, wherein the connecting part has a threaded hole, and the extending portion of the locking part has external threads matching the threaded hole.

3. The LCD device according to claim 2, wherein the connecting part is a rivet nut; the locking part is a screw.

4. The LCD device according to claim 2, wherein the connecting part is a nut; the locking part is a bolt.

5. The LCD device according to claim 1, wherein the connecting part is fixed on the side of the display panel by glue.

6. The LCD device according to claim 1, wherein the display panel includes an upper substrate, a lower substrate, and a liquid crystal layer between the upper and lower substrates; the connecting part is stuck on an outer side of the lower substrate.

7. The LCD device according to claim 6, further comprising a polarizer between the lower substrate and the connecting part.

8. The LCD device according to claim 1, further comprising a light guide plate and a plurality of optical films between the display panel and the back cover, the optical films having a perforation, so that the connecting part penetrates the perforation of the optical films.

9. The LCD device according to claim 1, wherein the mold frame is disposed on a periphery of the display panel and coupled to edges of the back cover.

10. An LCD device, comprising:
a display panel;
a connecting part fixed on one side of the display panel;
a back cover disposed on the side of the display panel having the connecting part, and having a through hole corresponding to the connecting part; and
a locking part comprising a base and an extending portion extending from the base, the base abutting against the back cover, and the extending portion penetrating the through hole and locked in the connecting part, so that the display panel is fixed on the back cover.

11. The LCD device according to claim 10, wherein the connecting part has a threaded hole, and the extending portion of the locking part has external threads matching the threaded hole.

12. The LCD device according to claim 11, wherein the connecting part is a rivet nut; the locking part is a screw.

13. The LCD device according to claim 11, wherein the connecting part is a nut; the locking part is a bolt.

14. The LCD device according to claim 10, wherein the connecting part is fixed on the side of the display panel by glue.

15. The LCD device according to claim 10, wherein the display panel includes an upper substrate, a lower substrate, and a liquid crystal layer between the upper and lower substrates; the connecting part is stuck on an outer side of the lower substrate.

16. The LCD device according to claim 15, further comprising a polarizer between the lower substrate and the connecting part.

17. The LCD device according to claim 10, further comprising a light guide plate and a plurality of optical films between the display panel and the back cover, the optical films having a perforation, so that the connecting part penetrates the perforation of the optical films.

18. The LCD device according to claim 10, further comprising a mold frame disposed between the display panel and the back cover, the mold frame utilized to support the display panel on the back cover.

19. The LCD device according to claim 18, wherein the mold frame is disposed on a periphery of the display panel and coupled to edges of the back cover.
